(19) United States
(12) Patent Application Publication
(10) Pub. No.: US 2010/0199952 A1
(43) Pub. Date: Aug. 12, 2010

(54) PIEZOELECTRIC ACTUATOR MODULE WITH A PROTECTIVE LAYER SYSTEM, AND A METHOD FOR ITS PRODUCTION

(76) Inventor: Nicole Schlegl, Rudersberg (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/676,069

(22) PCT Filed: Jul. 22, 2008
(86) PCT No.: PCT/EP08/59572

§ 371 Date: Mar. 2, 2010

(30) Foreign Application Priority Data
Sep. 6, 2007 (DE) 10 2007 042 400.2

(51) Int. Cl. F02M 51/06; H01L 41/22; H01L 41/053

(52) U.S. Cl. 123/472; 29/25.35; 310/340

(57) ABSTRACT

A piezoelectric actuator module is proposed having one or a plurality of piezoelectric actuators which is or are clamped in between an actuator head and an actuator base. According to the invention, at least the piezoelectric actuator is provided with a protection layer system. Provision is made of at least one surrounding element for tightly fixing the protection layer system to the actuator head, to the actuator base and/or to the piezoelectric actuator. The at least one surrounding element is composed of a material having a shape memory and can be pressed onto the protection layer system after a mounting-dictated expansion.

### PRIOR ART

The invention relates to a piezoelectric actuator module having a protection layer system and to a method for its production, as generically defined by the preambles to the main claim and to the coordinate method claim.

A piezoelectric actuator module of this kind can be used for instance in a piezoelectric injector for precise metering of fuel in terms of timing and quantity in an internal combustion engine. The piezoelectric injector essentially comprises a holder body for the piezoelectric actuator module and at least one piezoelectric actuator, disposed in the piezoelectric actuator module, having piezoelectric elements stacked one above the other and disposed between an actuator head and an actuator base, each of which comprises piezoelectric layers enclosed by inner electrodes.

With the use of a material of a suitable crystalline structure (piezoelectric ceramic) for the piezoelectric layers, the piezoelectric elements of the piezoelectric actuator are constructed in such a way that when an external voltage is applied to the inner electrodes, a mechanical reaction of the piezoelectric elements ensues, which as a function of the crystalline structure and the contact regions of the electrical voltage represents a compression or tension in a predeterminable direction. In the case of a piezoelectric injector, the piezoelectric actuator is connected a nozzle needle, so that by application of a voltage to the piezoelectric elements, a nozzle opening is uncovered.

These common rail injectors can be constructed in such a way that a nozzle needle controlled indirectly by the piezoelectric actuator is present, and the piezoelectric actuator is surrounded directly or indirectly by the pressure of the fuel, and only a hydraulic coupling chamber is provided between the nozzle needle and the piezoelectric actuator. If the piezoelectric actuators are located in the low-pressure range of the fuel (approximately 60 bar), as is the case with indirectly controlled needle motions, then a metal sleeve seal of the piezoelectric actuator can certainly be achieved with a membrane as a stroke-compensating and/or temperature-compensating element.

In Diesel kinks, in what is called direct nozzle needle control, the piezoelectric actuators are operated directly in the Diesel fuel at high pressure (approximately 2000 bar); the aforementioned relatively rigid sleeve/diaphragm seal would not withstand the high system pressures and the greater reciprocating motions of the piezoelectric actuator, given the space available.

To protect the piezoelectric elements of the piezoelectric actuator, for instance in view of their electrical insulation as well, it is therefore also known to sheathe the piezoelectric actuator with an elastomer. Since the presence of fuel, especially with regard to its conductive components, on the surface of the piezoelectric actuator can lead to an electric sparkover between the electrodes and thus to the failure of the piezoelectric actuator, the piezoelectric actuator must be protected against direct contact with the fuel, including by means of suitable tightness at the seam or connection locations.

From German Patent Disclosure DE 101 39 871 A1, a piezoelectric injector with an actuator module acting on a valve member via a hydraulic pressure booster is known in which the piezoelectric elements of the piezoelectric actuator are disposed in a sheath provided with a metal bellows.

From International Patent Disclosure WO 2001 48834 A2, it is known that the electrical insulation of a piezoelectric actuator is provided by means of a protective jacket of plastic, which is applied for instance by injection molding. From U.S. Pat. No. 7,036,198 B2, it is also known that this protection layer system is formed of a shrink-on hose, which by means of a shrinkage process brings about the sealing relative to the surrounding medium.

The critical points of the seal are the attachments of the ends of the sheath or of the protection layer system, particularly to the actuator head and/or to the actuator base, so that good tightness is durably assured there as well.

### DISCLOSURE OF THE INVENTION

The invention is based on a piezoelectric actuator module as described at the outset, having one or more piezoelectric actuators, which is or are fastened between an actuator head and an actuator base, and in which at least the piezoelectric actuator is provided with a protection layer system. According to the invention, a surrounding element for fastening the protection layer system to the actuator head, the actuator base, and/or the piezoelectric actuator, is provided which advantageously comprises a material having a shape memory and, after widening that is required for assembly, can be pressed onto the protection layer system. Preferably, to that end, the at least one surrounding element for contact with the protection layer system comprises a shape memory material, preferably an NiTi alloy (such as an NiTi=nickel-titanium alloy in which the proportions are 50/50) or an NiTiCu alloy.

The protection layer system of the piezoelectric actuator module of the invention, as a result of the proposed use of what are known as shape memory materials (shape memory alloys) is attached by simple means, durably and solidly, to the actuator head and/or the actuator base of the piezoelectric actuator module and is thus sealed off from the surrounding media, such as fuel.

From German Patent Disclosure DE 10 2005 045 230 A1, it is known per se that to insulate a conductor, a ring of shape memory material is provided, which is cold-widened and then, by being subjected to heat, is restored to the shape it had before it was widened.

The special advantage of using the materials according to the invention is thus that in certain regions, the shape memory materials exhibit what is called superelasticity or pseudoelasticity. In this region, they can be elongated mechanically by up to approximately 8% without deforming plastically. That is, the proposed surrounding elements, for instance comprising the corresponding NiTi alloys, in a version as a spring or ring, can be widened greatly, unlike the springs or rings made from conventional materials, and can thus be slipped over onto the actuator head or the actuator base without losing their later tensing or clamping force.

This allows greater degrees of freedom in the structural design of the actuator head or actuator base, so that larger diameters are possible, and a two-part design may possibly not even be necessary. On the other hand, the assembly of the components of the piezoelectric actuator module is simplified considerably, since mechanical widening of the surrounding element for simple assembly is possible within relatively wide limits, and furthermore, the tensing or clamping force can be adjusted in advance by way of the degree of widening.

In an advantageous method for producing a piezoelectric actuator module, in a first method step, the piezoelectric actuator and at least some portions of the actuator head and/or of the actuator base are coated with the protection layer system; in a second method step, the surrounding element of a material having a shape memory is widened within predetermined limits and is slipped onto the protection layer system in the region of the actuator head and/or of the actuator base; and/or in a further method step, preferably by a thermal process, the surrounding element is pressed onto the protection layer system at the actuator head and/or at the actuator base.

The assembly of a sufficiently large surrounding element is even possible without prior widening; in that case, the pressing is accomplished only by the shape memory effect, by means of a reduction in size by heating.

The piezoelectric actuator module according to the invention can advantageously be formed with a protection layer system of one or more layers of a polymer or metal material. This kind of proposed attachment of the protection layer system is especially advantageous whenever welding or soldering of the protection layer system is not possible, particularly in the case where a polymeric protection system, such as a shrink-on hose or shaped hose, is used.

### BRIEF DESCRIPTION OF THE DRAWINGS

The invention will be described below in terms of the exemplary embodiment shown in the drawings. In the drawings:

FIG. 1 shows a section through a piezoelectric actuator module with a piezoelectric actuator, an actuator head, an actuator base, and with a protection layer system, surrounding the piezoelectric actuator, that is attached by surrounding elements to the actuator head and to the actuator base; and

FIG. 2 shows a section, based on FIG. 1, with the protection layer system and the surrounding elements shown in greater detail.

### EMBODIMENTS OF THE INVENTION

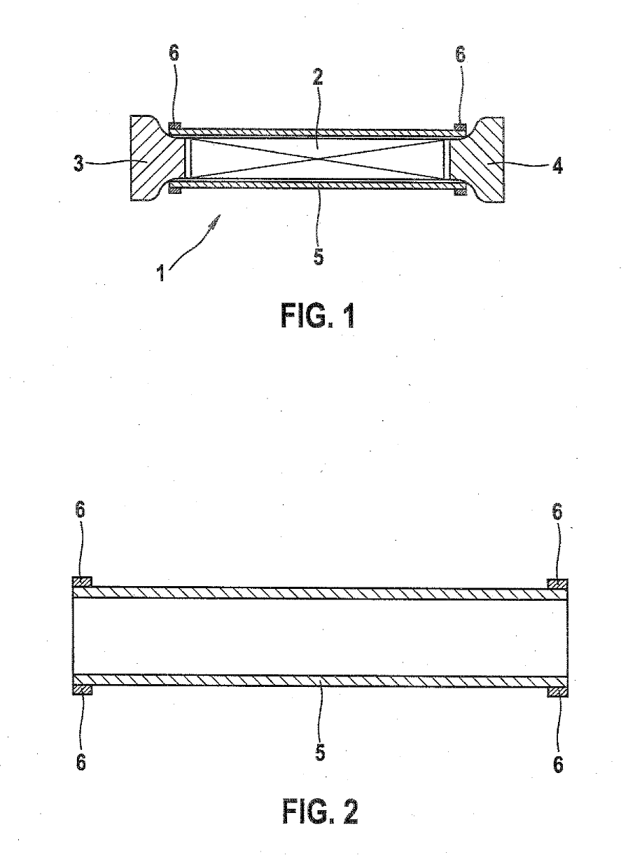

In FIG. 1, a piezoelectric actuator module 1, for instance for a piezoelectric injector, is shown in section; it can be used for needle stroke control in an injection system for fuel in an internal combustion engine, as has been described at the outset in terms of the prior art.

The piezoelectric actuator module 1 has a piezoelectric actuator 2 or a series of a plurality of such piezoelectric actuators 2, which are constructed with the piezoelectric elements described in the prior art section for effecting a mechanical stroke in the length of the piezoelectric actuator module 1. An actuator head 3 is shown here on the left face end of the piezoelectric actuator 2, and an actuator base 4 is shown on the right face end of the piezoelectric actuator 2. The piezoelectric actuator 2 is sheathed by a protection layer system 5 comprising one or more layers, which is sealingly attached mechanically to the actuator head 3 and the actuator base 4 by means of the surrounding elements 6.

FIG. 2 shows a more-detailed section of the protection layer system 5, having the surrounding elements 6 for fastening the protection layer system 5 to the actuator head 3, the actuator base 4, and/or the piezoelectric actuator 2, which comprises a material with what is known as shape memory and which, after widening required for assembly, can be pressed onto the protection layer system 5.

For that purpose, the surrounding elements 6 for contact with the protection layer system 5 are preferably made from a shape memory material, preferably an NiTi alloy or an NiTiCu alloy. These shape memory materials can be cold-widened and then, by being subjected to heat, be returned to the shape they had before they were widened, without plastic deformation.

In the production of the piezoelectric actuator module 1, the surrounding elements 5 can be widened within predeterminable limits after the protection layer system 5 has been attached and can be slipped onto the protection layer system 5 in the region of the actuator head 3 and/or the actuator base 4 and past them. By reverse expansion in the elastic range or by subjection to heat, the surrounding elements 6 can then be pressed onto the protection layer system 5 at the actuator head 3 and/or the actuator base 4.

The protection layer system 5 of the piezoelectric actuator module 1 of the invention, by the proposed use of shape memory materials (shape memory alloys) for the surrounding elements 6, can be attached by simple means, durably and solidly, to the actuator head 3 and/or the actuator base 4 of the piezoelectric actuator module 1, and thus the piezoelectric actuator module is sealed off from the surrounding media, such as fuel.

1-5. (canceled)

6. A piezoelectric actuator module, comprising:
one or more piezoelectric actuators that are fastened between an actuator head and an actuator base;
a protection layer system provided for the at least the piezoelectric actuator; and
at least one surrounding element for tight fastening of the protection layer system to the actuator head being provided on the actuator base and/or on the piezoelectric actuator, wherein
the at least one surrounding element comprises a material having a shape memory and after an assembly-dictated widening and/or a thermal treatment which can be pressed onto the protection layer system.

7. The piezoelectric actuator module as defined by claim 6, wherein the at least one surrounding element for contact with the protection layer system comprises a shape memory material, preferably an NiTi or NiTiCu alloy.

8. The piezoelectric actuator module as defined by claim 6, wherein the protection layer system comprises one or more layers of a polymer or metal material.

9. The piezoelectric actuator module as defined by claim 7, wherein the protection layer system comprises one or more layers of a polymer or metal material.

10. A method for producing a piezoelectric actuator module as defined by claim 6, comprising the steps of:
in a first method step, coating the piezoelectric actuator and at least some portions of the actuator head and/or of the actuator base with the protection layer system;
in a second method step, widening the surrounding element of a material having a shape memory within predetermined limits and slipping the surrounding element onto the protection layer system in a region of the actuator head and/or of the actuator base;
and/or in a further method step, preferably by a thermal process, pressing the surrounding element onto the protection layer system at the actuator head and/or at the actuator base.

11. A method for producing a piezoelectric actuator module as defined by claim 7, comprising the steps of:
in a first method step, coating the piezoelectric actuator and at least some portions of the actuator head and/or of the actuator base with the protection layer system;
in a second method step, widening the surrounding element of a material having a shape memory within predetermined limits and slipping the surrounding element onto the protection layer system in a region of the actuator head and/or of the actuator base;
and/or in a further method step, preferably by a thermal process, pressing the surrounding element onto the protection layer system at the actuator head and/or at the actuator base.

12. A method for producing a piezoelectric actuator module as defined by claim 8, comprising the steps of:
in a first method step, coating the piezoelectric actuator and at least some portions of the actuator head and/or of the actuator base with the protection layer system;
in a second method step, widening the surrounding element of a material having a shape memory within predetermined limits and slipping the surrounding element onto the protection layer system in a region of the actuator head and/or of the actuator base;
and/or in a further method step, preferably by a thermal process, pressing the surrounding element onto the protection layer system at the actuator head and/or at the actuator base.

13. A method for producing a piezoelectric actuator module as defined by claim 9, comprising the steps of
in a first method step, coating the piezoelectric actuator and at least some portions of the actuator head and/or of the actuator base with the protection layer system;
in a second method step, widening the surrounding element of a material having a shape memory within predetermined limits and slipping the surrounding element onto the protection layer system in a region of the actuator head and/or of the actuator base;
and/or in a further method step, preferably by a thermal process, pressing the surrounding element onto the protection layer system at the actuator head and/or at the actuator base.

14. A use of a piezoelectric actuator module as defined by claim 6, wherein the piezoelectric actuator is a component of a piezoelectric injector for an injection system for fuel in an internal combustion engine, in which the fuel bathes the protection layer system.

15. A use of a piezoelectric actuator module as defined by claim 7, wherein the piezoelectric actuator is a component of a piezoelectric injector for an injection system for fuel in an internal combustion engine, in which the fuel bathes the protection layer system.

16. A use of a piezoelectric actuator module as defined by claim 8, wherein the piezoelectric actuator is a component of a piezoelectric injector for an injection system for fuel in an internal combustion engine, in which the fuel bathes the protection layer system.

17. A use of a piezoelectric actuator module as defined by claim 9, wherein the piezoelectric actuator is a component of a piezoelectric injector for an injection system for fuel in an internal combustion engine, in which the fuel bathes the protection layer system.

18. A use of a piezoelectric actuator module as defined by claim 10, wherein the piezoelectric actuator is a component of a piezoelectric injector for an injection system for fuel in an internal combustion engine, in which the fuel bathes the protection layer system.

19. A use of a piezoelectric actuator module as defined by claim 11, wherein the piezoelectric actuator is a component of a piezoelectric injector for an injection system for fuel in an internal combustion engine, in which the fuel bathes the protection layer system.

20. A use of a piezoelectric actuator module as defined by claim 12, wherein the piezoelectric actuator is a component of a piezoelectric injector for an injection system for fuel in an internal combustion engine, in which the fuel bathes the protection layer system.

21. A use of a piezoelectric actuator module as defined by claim 13, wherein the piezoelectric actuator is a component of a piezoelectric injector for an injection system for fuel in an internal combustion engine, in which the fuel bathes the protection layer system.
